(19) United States
(12) Patent Application Publication
(10) Pub. No.: US 2026/0173738 A1
(43) Pub. Date: Jun. 18, 2026

(54) DISPLAY DEVICE INCLUDING A LOW-REFRACTIVE LAYER AND METHOD FOR FABRICATING THE SAME

(71) Applicant: SAMSUNG DISPLAY CO., LTD., YONGIN-SI (KR)

(72) Inventor: Hyung Guen YOON, Yongin-si (KR)

(21) Appl. No.: 19/249,258

(22) Filed: Jun. 25, 2025

(30) Foreign Application Priority Data
Dec. 17, 2024 (KR) 10-2024-0187951

(51) Int. Cl. H10K 59/80; H10K 59/12; H10K 59/38; H10K 102/00

(52) U.S. Cl. CPC H10K 59/879; H10K 59/1201; H10K 59/38; H10K 2102/351

(57) ABSTRACT

The present invention relates to display device and method for fabricating the same. The display device includes a substrate, a light-emitting element disposed on the substrate, where the light-emitting element is configured to emit a first light having a first wavelength range, a color conversion layer disposed on the light-emitting element and configured to convert the first light into a second light having a second wavelength range different from the first wavelength range, a low-refractive layer disposed on the color conversion layer, and a color filter layer disposed on the low-refractive layer, where the low-refractive layer includes silicon oxide (SiOₓ) having a porosity of 20% to 80%, and has a haze of 0.5% or less.

This non-provisional patent application claims priority under 35 U.S.C. § 119 to Korean Patent Application No. 10-2024-0187951 filed on Dec. 17, 2024 in the Korean Intellectual Property Office, the disclosure of which is incorporated herein by reference in its entirety.

### TECHNICAL FIELD

The present disclosure relates to a display device and, more specifically, to a display device including a low-refractive layer and a method for fabricating the same.

### Discussion of the Related Art

With the development of the information-oriented society, demands for various display devices are increasing. For example, display devices are used in a variety of electronic devices including smart phones, digital cameras, laptop computers, navigation devices, and smart televisions.

In some cases, display devices may be flat panel display devices such as a liquid-crystal display device, a field emission display device, and a light-emitting display device. Light-emitting display devices may include an organic light-emitting display device, which includes an organic light-emitting element. Some light-emitting display devices may include an inorganic light-emitting display device which includes an inorganic light-emitting element such as an inorganic semiconductor. Some light-emitting display devices may include a micro-light-emitting display device which includes an ultra-small light-emitting element.

An organic light-emitting display device displays images by using light-emitting elements each including an emissive layer of an organic luminescence material. As an organic light-emitting display device displays images by using self-luminous elements, the organic light-emitting display device can exhibit superior performance in power consumption, response speed, emission efficiency, luminance, and wide viewing angle.

In a display device, the display surface of the display device from which light is emitted may include a display area that displays images and a non-display area surrounding the display area. Emission areas may be disposed in the display area, which emit lights with respective luminance and colors.

### SUMMARY

Aspects of the present disclosure provide a display device that improves light efficiency without a capping layer, by disposing a low-refractive layer of an inorganic material including a cavity between a color conversion layer and a color filter layer.

It should be noted that objects of the present disclosure are not necessarily limited to the example described above. Additional objectives of the present disclosure are apparent to those skilled in the art from the following descriptions.

According to an aspect of the present disclosure, a display device includes a substrate, a light-emitting element disposed on the substrate, where the light-emitting element is configured to emit a first light having a first wavelength range, a color conversion layer disposed on the light-emitting element and configured to convert the first light into a second light having a second wavelength range different from the first wavelength range, a low-refractive layer disposed on the color conversion layer, and a color filter layer disposed on the low-refractive layer, where the low-refractive layer is silicon oxide (SiOₓ) having a porosity of 20% to 80%, and has a haze of 0.5% or less.

A refractive index of the low-refractive layer ranges from 1.0 to 1.4.

The low-refractive layer includes a plurality of pores, where each pore of the plurality of pores has a diameter ranging from 10 nm to 50 nm.

The plurality of pores of the low-refractive layer are substantially spherical.

The low-refractive layer has a thickness of 0.5μm to 2.0μm.

According to an aspect of the present disclosure, a method for fabricating a display device includes mixing perhydropolysilazane (PHPS) or polydimethylsiloxane (PDMS), hollow silica, and a solvent to form a mixed solution, forming a color filter layer on a substrate, applying the mixed solution onto the color filter layer, forming a low-refractive layer by irradiating at least one of ultraviolet rays, ozone or plasma onto the mixed solution, and forming a color conversion layer on the low-refractive layer.

100 parts by weight of the mixed solution comprises 45 to 70 parts by weight of perhydropolysilazane (PHPS) or polydimethylsiloxane (PDMS), 10 to 40 parts by weight of the hollow silica, and 10 to 20 parts by weight of the solvent.

The hollow silica includes a cavity having a diameter ranging from 10 nm to 50 nm.

The solvent includes at least one of xylene, toluene, anisole, butyl ether or dibutyl ether.

The ultraviolet rays have a wavelength of 190 nm or less.

The method further includes removing the solvent from mixed solution on the color filter layer.

Removing the solvent includes performing at least one of heat treatment or vacuum treatment.

The method further includes forming hydroxyl groups on a surface of the hollow silica.

Forming the hydroxyl groups on the surface of the hollow silica includes mixing the hollow silica with sodium hydroxide (NaOH).

Forming the hydroxyl groups on the surface of the hollow silica includes exposing the hollow silica to atmospheric oxygen.

A haze of the low-refractive layer is equal to or less than 0.5%.

A refractive index of the low-refractive layer ranges from 1.0 m to 1.4.

The hollow silica has a substantially spherical cross-sectional shape.

The low-refractive layer has a thickness ranging from 0.5 μm to 2.0 μm.

According to an aspect of the present disclosure, an electronic device includes a display device for displaying images, where the display device includes a substrate, a light-emitting element disposed on the substrate, where the light-emitting element is configured to emit a first light having a first wavelength range, a color conversion layer disposed on the light-emitting element and configured to convert the first light into a second light having a second wavelength range different from the first wavelength range, a low-refractive layer disposed on the color conversion layer, and a color filter layer disposed on the low-refractive layer, and where the low-refractive layer comprises silicon oxide (SiOₓ) having a porosity of 20% to 80%, and has a haze of 0.5% or less.

According to embodiments of the present disclosure, by applying an inorganic material instead of an organic material on a color conversion layer in a display device, the amount of a solvent for forming a low-refractive layer can be reduced. By doing so, a capping layer for preventing damage to a color conversion layer can be eliminated and the low-refractive layer can be formed directly, and thus the fabrication cost can be saved.

In addition, by using a host with a low refractive index, such as an inorganic material instead of an organic material, the refractive index of the low-refractive layer can be sufficiently low even though the content of hollow silica is reduced.

It should be noted that effects of the present disclosure are not necessarily limited to those described above and other effects of the present disclosure will be apparent to those skilled in the art from the following descriptions.

### BRIEF DESCRIPTION OF THE DRAWINGS

The above and other aspects and features of the present disclosure will become apparent through detailed description of exemplary embodiments thereof with reference to the attached drawings.

FIG. 1 is a plan view showing a display device according to an embodiment of the present disclosure.

FIG. 2 is a cross-sectional view taken along line A-A′ of the display device in FIG. 1.

FIG. 3 is a view showing the display area and the circuit layer of portion B of the display device shown in FIG. 1.

FIG. 4 is a block diagram showing the circuit layer of portion D shown in FIG. 3.

FIG. 5 is an equivalent circuit diagram of an emission pixel driver shown in FIG. 4.

FIG. 6 is a cross-sectional view taken along line E-E′ of FIG. 3.

FIG. 7 is a block diagram of an electronic device according to an embodiment of the present disclosure.

FIG. 8 is a view showing electronic devices according to embodiments of the present disclosure.

FIG. 9 is a cross-sectional view showing the low-refractive layer in area F of FIG. 6.

FIG. 10 is a flowchart for illustrating a method for fabricating a display device according to an embodiment of the present disclosure.

### DETAILED DESCRIPTION OF THE EMBODIMENTS

The features of the present invention, and the methods for achieving the features, are described in detail with reference to the embodiments below with the accompanying drawings. However, the present invention is not necessarily limited to the embodiments disclosed below, but may be implemented in various different forms, and these embodiments are provided only to make the disclosure of the present invention complete and to fully inform those skilled in the art of the invention of the scope of the invention, and the present invention is defined by the scope of the claims.

When elements or layers are referred to as “on” another element or layer, this includes cases where another layer or another element is interposed directly over or in the middle of the other element. The same reference numerals refer to the same components throughout the specification. The shapes, sizes, ratios, angles, numbers, etc. disclosed in the drawings for explaining the embodiments are exemplary, and therefore the present invention is not necessarily limited to the matters illustrated. To the extent that an element is not described in detail with respect to a figure, it may be understood that the element is at least similar to a corresponding element that has been described elsewhere within the present disclosure.

Although the terms “first” and “second” are used to describe various components, these components are not necessarily limited by these terms. These terms are used to distinguish one component from another. Therefore, in some cases, the first component mentioned below may be the second component within the technical idea of the present invention.

Each of the features of the various embodiments of the present invention may be partially or wholly combined or combined with each other, and various technical connections and operations are possible, and each embodiment may be implemented independently of each other or may be implemented together in a related relationship.

Specific embodiments will be described below with reference to the attached drawings. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Hereinafter, exemplary embodiments of the present disclosure will be described in detail with reference to the accompanying drawings.

Embodiments of the present disclosure provide a low-refractive layer for a display device, the low-refractive layer includes a silicon oxide matrix having uniformly distributed pores formed by hollow silica particles, resulting in a refractive index ranging from approximately 1.0 to 1.4. The low-refractive layer is disposed between a color filter layer and a color conversion layer, and is configured to enhance light emission efficiency by increasing total internal reflection at the refractive index boundary. In some embodiments, the low-refractive layer is formed using an inorganic solution containing perhydropolysilazane (PHPS) or polydimethylsiloxane (PDMS). Accordingly, by disposing the low-refractive layer between the color filter layer and the color conversion layer, embodiments of the present disclosure improve light efficiency without a capping layer.

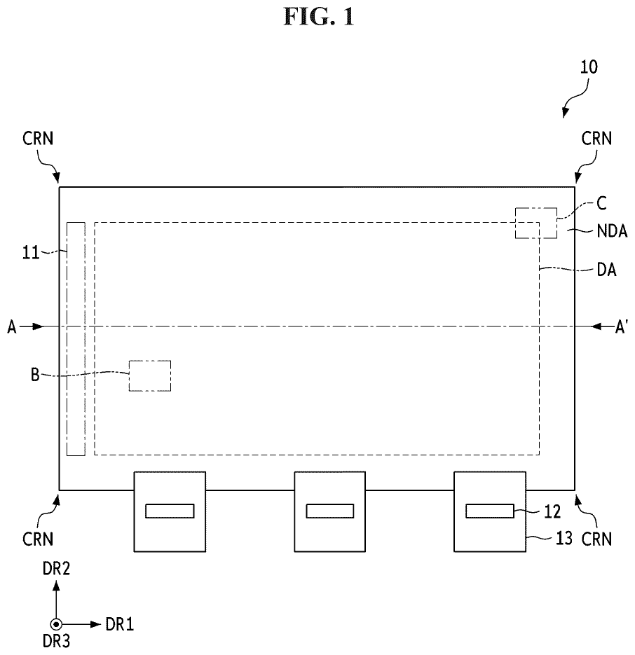

FIG. 1 is a plan view showing a display device according to an embodiment of the present disclosure.

Referring to FIG. 1, a display device 10 according to an embodiment of the present disclosure is configured to display moving images or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of a variety of electronic devices such as a television, a notebook, a monitor, a billboard and the Internet of Things (IoT) devices.

The display device 10 may be a light-emitting display device such as an organic light-emitting display device using organic light-emitting diodes, an inorganic light-emitting display device using an inorganic semiconductor, and/or a micro light-emitting display device using micro or nano light-emitting diodes (micro LEDs or nano LEDs). In the following description, an organic light-emitting display device is used in the display device 10. It should be understood, however, that the present disclosure is not necessarily limited thereto. A display device including an organic insulating material, an organic luminescent material and a metal material may be used in the display device 10.

The display device 10 may be formed flat, but is not necessarily limited thereto. For example, the display device 10 may include curved portions at the left and right ends, having a constant curvature or varying curvatures. In addition, the display device 10 may be flexible so that the display device 10 can be curved, bent, folded or rolled.

According to an exemplary embodiment, the display device 10 may be an organic light-emitting display device.

As shown in FIG. 1, the display device 10 according to the embodiments may include a surface having a rectangular shape. It should be understood, however, that the rectangular shape is merely illustrative. The shape of the display device 10 is not necessarily limited to the shape shown in FIG. 1. For example, the display device 10 according to the embodiments may include a surface having a polygonal shape other than a rectangular shape, or a circular shape. Alternatively, at least a part of the display device 10 may be deformed from an unfolded shape to a bent, curved, folded, or rolled shape.

The surface of the display device 10 may include a display area DA where light is emitted for displaying images, and a non-display area NDA surrounding the display area DA. In some cases, the surface of the display device 10 may further include a protective layer, such as a cover glass, a transparent polymer film, or a laminated structure. The protective layer may provide mechanical durability, environmental resistance, or optical enhancements to the display device 10.

The display area DA may be disposed over most of the surface of display device 10.

The non-display area NDA may be in a frame shape surrounding the display area DA where no light is emitted for displaying images. For example, the non-display area NDA may be maintained in a particular color such as black.

The surface of the display device 10 may include corners CRN where the intersecting sides meet each other. For example, if the surface of the display device 10 is in a rectangular shape, the surface of the display device 10 may include four corners CRN. In some cases, the display area DA and the non-display area NDA may include integrated sensors, such as touch sensors, fingerprint sensors, proximity sensors, or light sensors. The integrated sensors may be disposed under the surface of the display device 10 or mounted within the display area DA or the non-display area NDA.

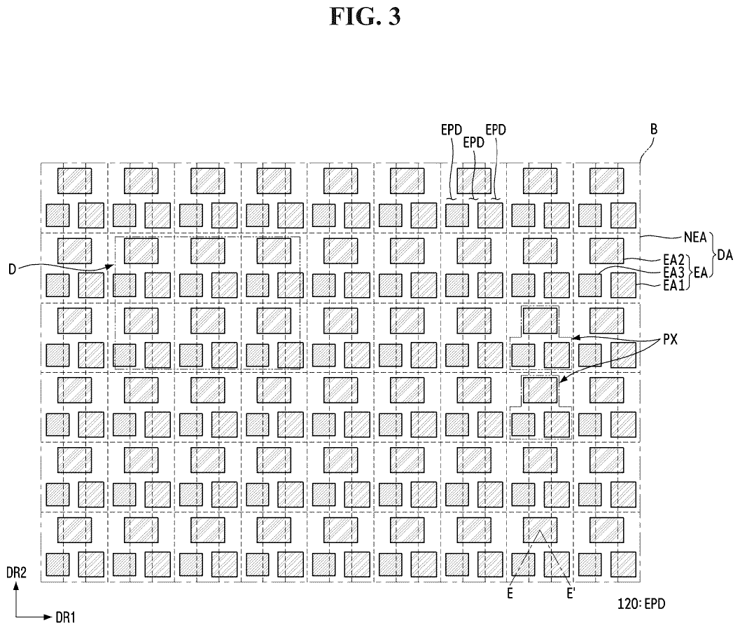

The display device 10 may include drivers 11 and 12 that transmit signals, voltages or power to emission pixel drivers EPD (see FIGS. 3, 4, and 5) disposed in the display area DA.

Among the drivers 11 and 12, some of the drivers 11, which can be implemented with relatively simple circuits, may be placed in the non-display area NDA.

Some others of the drivers 11 and 12 may be implemented as integrated circuit chips and may be mounted on circuit boards 13 electrically connected to pads in the non-display area NDA. Alternatively, some other drivers 12 may be mounted on the pads in the non-display area NDA. In an embodiment, some of the drivers 11 and 12 may be configured in a modular format, allowing the drivers to be separately fabricated and later integrated with the display device 10 via flexible printed circuits, or other suitable methods or structures.

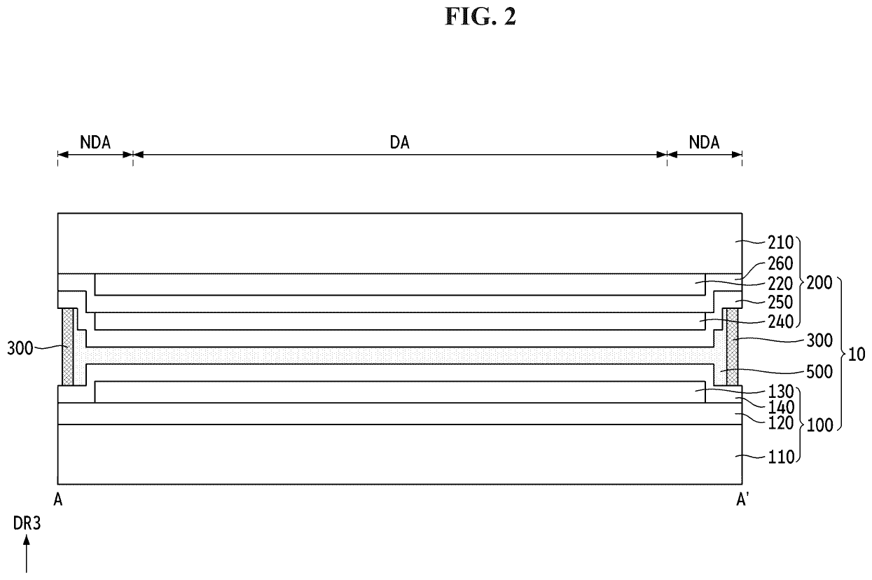

FIG. 2 is a cross-sectional view taken along line A - A′ of the display device in FIG. 1.

Referring to FIG. 2, a display device 10 according to the embodiment may include a first substrate 100 and a second substrate 200 that face each other, a sealing layer 300 disposed between the first substrate 100 and the second substrate 200 to attach the first substrate 100 to the second substrate 200.

The display device 10 according to the embodiment may further include a filling layer 500 configured to fill a space surrounded by the first substrate 100, the second substrate 200 and the sealing layer 300.

Each of the first substrate 100 and the second substrate 200 may include a display area DA where light for displaying images is emitted, and a non-display area NDA surrounding the display area DA where no light is emitted.

According to the embodiment, the first substrate 100 may include a first support substrate 110 that includes the display area DA and the non-display area NDA, and an element layer 130 disposed on the first support substrate 110.

The first substrate 100 may further include a circuit layer 120 disposed on the first support substrate 110, and an encapsulation layer 140 disposed on and covering the element layer 130.

The element layer 130 may be disposed on the circuit layer 120.

According to some embodiment, the first substrate 100 may include the first support substrate 110, the circuit layer 120 disposed on the first support substrate 110, the element layer 130 disposed on the circuit layer 120, and the encapsulation layer 140 disposed on the element layer 130. For example, the first substrate 100 may include a stacked structure including the first support substrate 110, the circuit layer 120, the element layer 130, and the encapsulation layer 140 sequentially stacked.

According to the embodiment, the second substrate 200 may include a second support substrate 210 including the display area DA and the non-display area NDA, and a color conversion layer 240 disposed on a surface of the second support substrate 210 facing the first support substrate 110.

The second substrate 200 may further include a color filter layer 220 disposed on the surface of the second support substrate 210, and a low-refractive layer 260 disposed on and covering the color filter layer 220.

The color conversion layer 240 may be disposed on the low-refractive layer 260.

The second substrate 200 may further include a color conversion capping layer 250 disposed on and covering the color conversion layer 240.

According to an embodiment, the second substrate 200 may include the second support substrate 210, the color filter layer 220 disposed on the surface of the second support substrate 210, the low-refractive layer 260 disposed on the color filter layer 220, the color conversion layer 240 disposed on the low-refractive layer 260, and the color conversion capping layer 250 disposed on the color conversion layer 240. For example, the second substrate 200 may include a stacked structure including the second support substrate 210, the color filter layer 220, the low-refractive layer 260, the color conversion layer 240, and the color conversion capping layer 250 sequentially stacked in a direction facing the first substrate 100. In an embodiment, one or more layers among the color filter layer 220, the low-refractive layer 260, and the color conversion layer 240 may be laminated as a pre-formed multilayer structure before being attached to the second support substrate 210.

According to the embodiment, the color conversion capping layer 250 may include an inorganic insulating material.

The sealing layer 300 may be disposed in the non-display area NDA between the first substrate 100 and the second substrate 200. The sealing layer 300 may be applied in a frame-like pattern along the boundary of the non-display area NDA to attach the first substrate 100 to the second substrate 200. In some cases, the sealing layer 300 may be connected to an upper surface of the encapsulation layer 140 and to a surface (that face the first substrate 100) of the color conversion capping layer 250.

FIG. 3 is a view showing the display area and the circuit layer of portion B of the display device shown in FIG. 1.

Referring to FIG. 3, the display area DA may include emission areas EA that emit light at respective luminance, and a non-emission area NEA disposed between the emission areas EA. In some cases, the display area DA may include a plurality of emission areas EA each including a first emission area EA1, a second emission area EA2, and a third emission area EA3.

According to the embodiment of the present disclosure, the emission areas EA may include a first emission area EA1 configured to emit light of a first wavelength range, a second emission area EA2 configured to emit light of a second wavelength range lower than the first wavelength range, and a third emission area EA3 configured to emit light of a third wavelength range lower than the second wavelength range.

For example, the first wavelength range may be approximately 600 nm to 750 nm, and light in the first wavelength range may be a red light. The second wavelength range may be approximately 480 nm to 560 nm, and light in the second wavelength range may be a green light. The third wavelength range may be approximately 370 nm to 460 nm, and light in the third wavelength range may be a blue light.

Accordingly, a unit pixel PX that displays white light may be formed by one or more first emission areas EA1, one or more second emission areas EA2, and one or more third emission areas EA3 that are adjacent to each other among the emission areas EA. In one embodiment, the unit pixel PX may include the first emission area EA1, the second emission area EA2, and the third emission area EA3 arranged in a stripe, delta, mosaic, or other similar configurations. The arrangement of emission areas EA within each unit pixel PX may vary based on resolution requirements or color rendering strategies of the display device 10.

According to an embodiment, the first emission areas EA1 and the third emission areas EA3 may be disposed alternately in the first direction DR1.

The second emission areas EA2 may be disposed in parallel in the first direction DR1.

The rows in which the first emission areas EA1 and the third emission areas EA3 are disposed alternately and the rows in which the second emission areas EA2 are disposed may alternate in the second direction DR2.

According to the embodiment, each of the second emission areas EA2 may be adjacent to a part of the first emission area EA1, a part of the third emission area EA3, and the non-emission area NEA disposed between the first emission area EA1 and the third emission area EA3 in the second direction DR2.

According to the embodiment, the distance between the adjacent second emission areas EA2 in the first direction DR1 may be greater than the distance between the first emission area EA1 and the third emission area EA3 adjacent to each other in the first direction DR1.

According to the embodiment, the third emission areas EA3 may be formed to have a smaller width than the first emission areas EA1 and the second emission areas EA2. The first emission areas EA1 may have a smaller width than the second emission areas EA2.

Each of the emission areas EA may be formed in a shape of a rectangle, a triangle, a diamond, a square, a trapezoid, a circle, or an ellipse.

The circuit layer 120 of the first substrate 100 may include emission pixel drivers EPD disposed in parallel with each other.

The emission pixel drivers EPD may be associated with the emission areas EA, respectively. Each emission pixel driver EPD may include a driving transistor, a storage capacitor, or a switching element, and may be configured to control the current supplied to a corresponding light-emitting element LE based on input data signals. In some cases, the emission pixel drivers EPD are disposed in the non-emission area NEA of the display device 10.

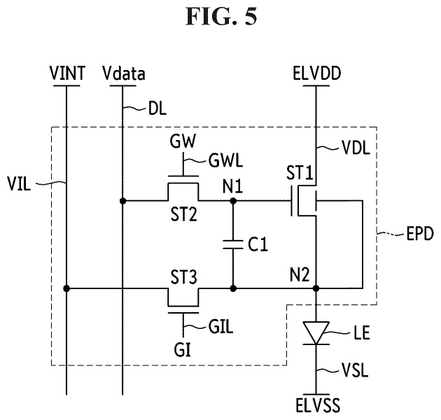

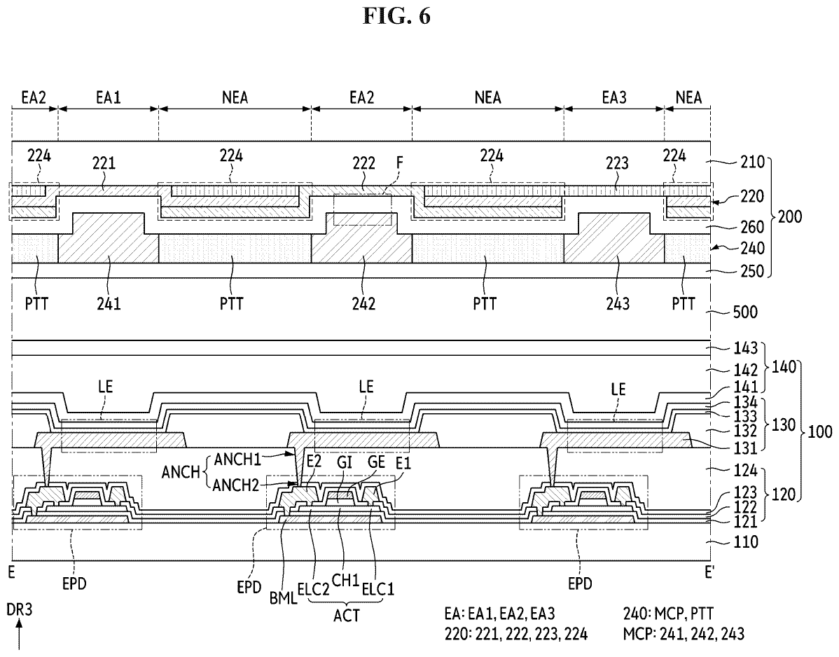

For example, the emission pixel drivers EPD may be electrically connected to the light-emitting elements LE (see FIGS. 5 and 6) of the element layer 130 (see FIG. 2) disposed in the emission areas EA.

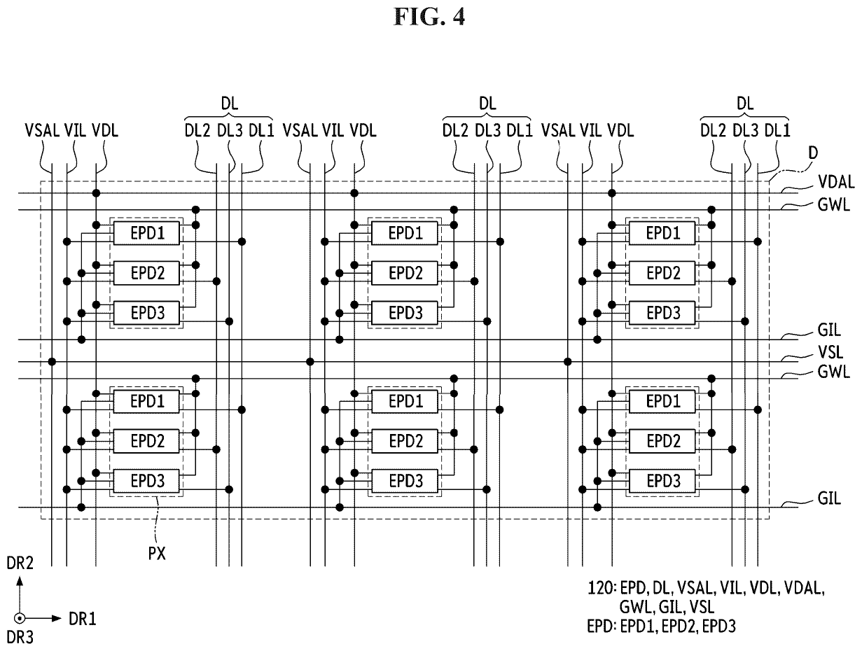

FIG. 4 is a block diagram showing the circuit layer of portion D shown in FIG. 3. The example illustrated in FIG. 4 shows the circuit layer 120, which includes the emission pixel drivers EPD and the associated lines, including the data line DL, the second auxiliary voltage line VSAL, the initialization voltage line VIL, the first voltage line VDL, the first auxiliary voltage line VDAL, the scan write line GWL, the scan initialization line GIL, and the second voltage line VSL. In one aspect, the emission pixel drivers EPD include the first emission pixel driver EPD1, the second emission pixel driver EPD2, and the third emission pixel driver EPD3.

Referring to FIG. 4, the circuit layer 120 may include emission pixel drivers EPD, and lines VDL, DL, VIL, GWL, and GIL electrically connected to the emission pixel drivers EPD.

The lines VDL, DL, VIL, GWL, and GIL may transmit voltage and/or power and signals to each of the emission pixel drivers EPD. In some cases, the lines VDL, DL, VIL, GWL, and GIL may be arranged in grouped layouts or staggered configurations based on the pixel arrangements and routing density of the circuit layer 120. In an embodiment, adjacent emission pixel drivers EPD may share a common signal or power line to reduce interconnect complexity.

For example, the circuit layer 120 may further include: a scan write line GWL for transmitting a scan write signal GW (see FIG. 5) to the emission pixel drivers EPD, a scan initialization line GIL for transmitting a scan initialization signal GI (see FIG. 5) to the emission pixel drivers EPD, a data line DL for transmitting a data signal Vdata (see FIG. 5) to the emission pixel drivers EPD, an initialization voltage line VIL for transmitting an initialization voltage VINT (see FIG. 5) to the emission pixel drivers EPD, a first voltage line VDL for transmitting a first supply voltage ELVDD (see FIG. 5) to the emission pixel drivers EPD, and a second voltage line VSL for transmitting a second supply voltage ELVSS (see FIG. 6) to the light-emitting elements LE (see FIG. 5).

The circuit layer 120 may further include a first auxiliary voltage line VDAL for reducing the resistance of the first voltage line VDL, and a second auxiliary voltage line VSAL for reducing the resistance of the second voltage line VSL.

The first auxiliary voltage line VDAL may be extended in a direction intersecting the first voltage line VDL and may be electrically connected to the first voltage line VDL.

The second auxiliary voltage line VSAL may be extended in a direction intersecting the second voltage line VSL and may be electrically connected to the second voltage line VSL.

The emission pixel drivers EPD may include a first emission pixel driver EPD1 electrically connected to the light-emitting element LE (see FIG. 5) of the first emission area EA1 (see FIG. 3), a second emission pixel driver EPD2 electrically connected to the light-emitting element LE (see FIG. 5) of the second emission area EA2 (see FIG. 3), and a third emission pixel driver EPD3 electrically connected to the light-emitting element LE (see FIG. 5) of the third emission area EA3 (see FIG. 3). In some embodiments, the first emission pixel driver EPD1, the second emission pixel driver EPD2, and the third emission pixel driver EPD3 may be configured with different drive current capabilities to accommodate differences in light-emitting element LE efficiency across the first, second, and third wavelength ranges.

The data lines DL may include a first data line DL1 that transmits the data signal Vdata (see FIG. 5) to the first emission pixel driver EPD1, a second data line DL2 that transmits the data signal Vdata (see FIG. 5) to the second emission pixel driver EPD2, and a third data line DL3 that transmits the data signal Vdata (see FIG. 5) of the third emission pixel driver EPD3.

FIG. 5 is an equivalent circuit diagram of an emission pixel driver shown in FIG. 4. FIG. 5 illustrates the internal circuit configuration of the emission pixel driver EPD, including components such as a capacitor C1, transistors ST1, ST2, and ST3, and a light-emitting element LE.

Referring to FIG. 5, the emission pixel driver EPD may be electrically connected between the first supply voltage ELVDD and the light-emitting element LE, and the light-emitting element LE may be electrically connected between the emission pixel driver EPD and the second supply voltage ELVSS.

The light-emitting element LE may be an organic light-emitting diode including an organic light-emitting layer, a quantum-dot LED including a quantum-dot light-emitting layer, a micro LED, or an inorganic LED including an inorganic semiconductor.

The second supply voltage ELVSS may have a lower voltage level than the first supply voltage ELVDD.

For example, a first emission electrode of the light-emitting element LE may be electrically connected to the emission pixel driver EPD, and a second emission electrode of the light-emitting element LE may be electrically connected to the second supply voltage ELVSS.

According to the embodiment, the light-emitting elements LE of the element layer 130 (see FIG. 2) may emit light of a fourth wavelength range that is lower than the third wavelength range. For example, the fourth wavelength range may be equal to or lower than the third wavelength range.

The emission pixel driver EPD may include a first transistor ST1 for generating a driving current of the light-emitting element LE, one or more transistors ST2 and ST3 electrically connected to the first transistor ST1, and at least one capacitor C1.

The first transistor ST1 may be electrically connected between the first voltage line VDL and the light-emitting element LE.

A first transistor electrode of the first transistor ST1 may be electrically connected to the first voltage line VDL.

A second transistor electrode of the first transistor ST1 may be electrically connected to a second node N2 and the first light-emitting electrode of the light-emitting element LE.

A first gate electrode of the first transistor ST1 may be electrically connected to a first node N1 and a second transistor ST2.

The second gate electrode of the first transistor ST1 may be electrically connected to the second node N2.

The second transistor ST2 may be electrically connected between the data line DL and the first node N1.

A gate electrode of the second transistor ST2 may be electrically connected to the scan write line GWL. For example, the second transistor ST2 may be turned on by a scan write signal GW of the scan write line GWL.

When the second transistor ST2 is turned on, the data signal Vdata of the data line DL may be transmitted to the first node N1.

By the data signal Vdata transmitted to the first node N1, the voltage difference between the gate electrode of the first transistor ST1 and the first transistor electrode of the first transistor ST1 (i.e., the voltage difference between the gate and the source) becomes the voltage difference between the first supply voltage ELVDD and the data signal Vdata, which may exceed the threshold voltage of the first transistor ST1. Accordingly, when the first transistor ST1 is turned on, a source-drain current having the magnitude corresponding to the data signal Vdata may be generated between the first transistor electrode and the second transistor electrode of the first transistor ST1. In addition, the source-drain current of the first transistor ST1 may be supplied as a driving current to the light-emitting element LE. In some cases, the magnitude of the driving current may be determined based on the difference between the data signal Vdata and a threshold voltage of the first transistor ST1.

Accordingly, the driving current proportional to the data signal Vdata is supplied to the light-emitting element LE, causing the light-emitting element LE to emit light having a luminance corresponding to the data signal Vdata.

The first capacitor C1 may be electrically connected between the first node N1 and the second node N2.

The first capacitor C1 may be charged by the data signal Vdata transmitted to the first node N1 through the turned-on second transistor ST2.

Accordingly, the potential of the first node N1 can be maintained for a certain period of time due to the voltage charged in the first capacitor C1. In some embodiments, the first capacitor C1 may also serve to compensate for leakage current at the first node N1 during emission.

The third transistor ST3 may be electrically connected between the initialization voltage line VIL and the second node N2.

A gate electrode of the third transistor ST3 may be electrically connected to the scan initialization line GIL. For example, the third transistor ST3 may be turned on by a scan initialization signal GI of the scan initialization line GIL.

When the third transistor ST3 is turned on, the potential of the second node N2, i.e., the potential of the first light-emitting electrode of the light-emitting element LE, may be initialized to the initialization voltage VINT of the initialization voltage line VIL.

As shown in FIG. 5, according to the embodiment, each of the first, second and third transistors ST1, ST2 and ST3 may be an n-type MOSFET. It should be understood, however, that the embodiments of the present disclosure are not necessarily limited thereto. At least one of the first, second and third transistors ST1, ST2 and ST3 may be a p-type MOSFET.

FIG. 6 is a cross-sectional view taken along line E-E′ of FIG. 3. In one aspect, FIG. 6 shows a structural configuration between components disposed on the first substrate 100 and the second substrate 200.

Referring to FIG. 6, the display device 10 may include the first substrate 100 and the second substrate 200 that face each other. The display device 10 further include a filling layer 500 disposed between the first substrate 100 and the second substrate 200, and filling the space therebetween.

The first substrate 100 may include the first support substrate 110, the circuit layer 120 disposed on the first support substrate 110, the element layer 130 including light-emitting elements LE disposed in emission areas EA and disposed on the circuit layer 120, and the encapsulation layer 140 disposed on and covering the element layer 130.

The first support substrate 110 may include the display area DA (see FIG. 1) and the non-display area NDA (see FIG. 1).

The display area DA may include the emission areas EA1, EA2 and EA3 (EA in FIG. 3) disposed in parallel, and the non-emission area NEA disposed between the emission areas EA1, EA2 and EA3 (EA in FIG. 3).

The circuit layer 120 may include a buffer layer 121 disposed on the first support substrate 110, a first interlayer dielectric layer 122 disposed on the buffer layer 121, a second interlayer dielectric layer 123 disposed on the first interlayer dielectric layer 122, and a planarization layer 124 disposed on the second interlayer dielectric layer 123.

Each of the buffer layer 121, the first interlayer dielectric layer 122 and the second interlayer dielectric layer 123 may include an inorganic insulating material.

The planarization layer 124 may include an organic insulating material. The planarization layer 124 may also reduce surface height variations across the circuit layer 120 (e.g., along the first direction DR1 and second direction DR2), thereby improving deposition of the element layer 130.

The circuit layer 120 may include emission pixel drivers EPD that transmit driving current to light emitting elements LE.

Each of the emission pixel drivers EPD may include two or more transistors ST1, ST2 and ST3 (see FIG. 5) and may be electrically connected to one or more lines DL, VDL, VIL, GWL and GIL (see FIG. 5).

The first transistor ST1 of each of the emission pixel drivers EPD may include an active layer ACT disposed on the buffer layer 121, a gate electrode GE disposed on a gate insulator GI covering a channel portion CH1 of the active layer ACT, and a first transistor electrode E1 and a second transistor electrode E2 disposed on the first interlayer dielectric layer 122 covering the active layer ACT and the gate electrode GE.

At least the channel portion CH1 of the active layer ACT may overlap with a light-blocking layer BML on the first support substrate 110.

The buffer layer 121 may cover the light-blocking layer BML.

The active layer ACT may include the channel portion CH1, a first transistor electrode portion ELC1 connected to one side of the channel portion CH1, and a second transistor electrode portion ELC2 connected to the opposite side of the channel portion CH1.

The first transistor electrode E1 may be electrically connected to the first transistor electrode portion ELC1 of the active layer ACT through a hole penetrating the first interlayer dielectric layer 122.

The second transistor electrode E2 may be electrically connected to the second transistor electrode portion ELC2 of the active layer ACT through a hole penetrating the first interlayer dielectric layer 122.

The second transistor electrode E2 may be electrically connected to the light-blocking layer BML through a hole penetrating the first interlayer dielectric layer 122 and the buffer layer 121.

The upper surface of the channel portion CH1 may face the gate electrode GE, and the rear surface of the channel portion CH1 may face the light-blocking layer BML electrically connected to the second transistor electrode E2.

Accordingly, depending on the potential of the light-blocking layer BML that is equal to the second transistor electrode E2, a portion of the active layer ACT, which is adjacent to the light-blocking layer BML, may be activated relatively weakly compared to another portion adjacent to the gate electrode GE.

The second interlayer dielectric layer 123 may cover the first interlayer dielectric layer 122, the first transistor electrode E1, and the second transistor electrode E2.

The planarization layer 124 may cover the second interlayer dielectric layer 123 and may include an organic insulating material.

The element layer 130 may be disposed on the planarization layer 124 of the circuit layer 120.

The element layer 130 includes light-emitting elements LE disposed in the emission areas EA. The light-emitting elements LE may emit light in the fourth wavelength range.

Each of the light-emitting elements LE may include a structure in which an emissive layer 133 is disposed between a first light-emitting electrode 131 and a second light-emitting electrode 134 that face each other.

Specifically, the element layer 130 may include first light-emitting electrodes 131 disposed in the emission areas EA on the circuit layer 120, a pixel-defining layer 132 disposed in the non-emission area NEA on the circuit layer 120 and covering the edges of the first light-emitting electrodes 131 the emissive layer 133 disposed on the first light-emitting electrodes 131, and the second light-emitting electrode 134 disposed on the emissive layer 133.

According to the embodiment, the emissive layer 133 may be further disposed on the pixel-defining layer 132 in the non-emission area NEA.

Alternatively, the emissive layer 133 may be disposed in each of the emission areas EA, with the emissive layers 133 spaced apart from each other.

The first light-emitting electrodes 131 may be electrically connected to the emission pixel drivers EPD through anode connection holes ANCH, respectively.

For example, the first light-emitting electrode 131 may be electrically connected to the second transistor electrode E2 of the first transistor ST1 of the emission pixel driver EPD through the anode connection hole ANCH.

The anode connection holes ANCH may penetrate the planarization layer 124 and the second interlayer dielectric layer 123. As shown in FIG. 6, the anode connection hole ANCH may include a multilayer structure including a first anchor portion ANCH1 and a second anchor portion ANCH2 to support vertical alignment and electrical connectivity. For example, the first anchor portion ANCH1 may penetrate the planarization layer 124, and the second anchor portion ANCH2 may penetrate the second interlayer dielectric layer 123.

The pixel-defining layer 132 may include an organic insulating material.

The emissive layer 133 may include an organic luminescence material.

The second light-emitting electrode 134 may be disposed in the display area DA including the emission areas EA1, EA2 and EA3 (e.g., EA in FIG. 3) and the non-emission area NEA.

The encapsulation layer 140 may include a first encapsulation layer 141 disposed on the element layer 130 and including an inorganic insulating material, a second encapsulation layer 142 disposed on the first encapsulation layer 141 and including an organic insulating material, and a third encapsulation layer 143 disposed on the second encapsulation layer 142 and including an inorganic insulating material.

By virtue of the encapsulation layer 140, the defects on the circuit layer 120 or the element layer 130 due to foreign substances can be reduced, and the defects by oxygen or moisture permeating into the circuit layer 120 or the element layer 130 can be delayed or prevented.

According to the embodiment, the second substrate 200 may include the color filter layer 220 disposed on the second support substrate 210, the low-refractive layer 260 disposed on and covering the color filter layer 220, the color conversion layer 240 disposed on the low-refractive layer 260, and the color conversion capping layer 250 disposed on and covering the color conversion layer 240 in a direction that faces the first support substrate 110.

The second support substrate 210 may include the display area DA (see FIG. 2) and the non-display area NDA (see FIG. 1).

In the direction in which light is emitted from the display device 10 (i.e., the third direction DR3), the low-refractive layer 260 may be disposed on the color conversion layer 240, the color filter layer 220 may be disposed on the low-refractive layer 260, and the second support substrate 210 may be disposed on the color filter layer 220. Accordingly, light emitted from the light-emitting elements LE of the element layer 130 may pass through the color conversion layer 240, the low-refractive layer 260, the color filter layer 220 and the second support substrate 210 to exit to the outside.

The color conversion layer 240 may include main converting portions MCP aligned with the respective emission areas EA disposed in the display area DA, and partition walls PTT disposed between the main converting portions MCP.

The main converting portions MCP may include a first color converting portion 241 aligned with the first emission area EA1, a second color converting portion 242 aligned with the second emission area EA2, and a light-transmitting portion 243 aligned with the third emission area EA3.

Each of the first color converting portion 241 and the second color converting portion 242 may convert light in the fourth wavelength range emitted from the light-emitting elements LE into light in another wavelength range.

The first color converting portion 241 may convert light emitted from the light-emitting element LE in the first emission area EA1 from the fourth wavelength range to the first wavelength range.

The second color converting portion 242 may convert light emitted from the light-emitting element LE in the second emission area EA2 from the fourth wavelength range to the second wavelength range.

The light-transmitting portion 243 may transmit and scatter light emitted from the light-emitting element LE in the third emission area EA3. As shown in FIG. 6, the first, second, and third emission areas EA1, EA2, and EA3 are respectively aligned with the corresponding color converting portions 241, 242, and 243, and with the color filter portions 221, 222, and 223, forming a vertically stacked light conversion and filtering path.

The first color converting portion 241 may be a cured product of a first ink material containing a base resin and first color-converting particles dispersed in the base resin. The first color-converting particles may convert light of the fourth wavelength range into light of the first wavelength range.

The second color converting portion 242 may be a cured product of a second ink material containing a base resin and second color-converting particles dispersed in the base resin. The second color-converting particles may convert light of the fourth wavelength range into light of the second wavelength range.

Each of the first color converting portion 241 and the second color converting portion 242 may further include scattering particles dispersed within the base resin.

Each of the first color converting particles and the second color converting particles may be at least one of a quantum dot, a quantum rod, or a phosphor.

The quantum dots may be a group IV nanocrystals, group II-VI compound nanocrystals, group III-V compound nanocrystals, group IV-VI nanocrystals, or combinations thereof.

The first color converting portion 241, the second color converting portion 242 and the light-transmitting portion 243 may include the same base resin, or may include different base resins. Each of the converting portions 241, 242, and 243 may be vertically aligned with corresponding filter portions 221, 222, and 223 in the color filter layer 220, respectively. This alignment ensures that each converted wavelength passes through the corresponding filter element.

### the light-transmitting portion 243 may include a base resin and scattering particles dispersed in the base resin.

The scattering particles may be metal oxide particles or organic particles.

The metal oxide particles may be at least one of titanium oxide (TiO₂), zirconium oxide (ZrO₂), aluminum oxide (Al₂O₃), indium oxide (In₂O₃), zinc oxide (ZnO), or tin oxide (SnO₂).

The organic particles may include an acrylic resin or a urethane resin.

The partition walls PTT may overlap at least a part of the non-emission area NEA and may be disposed between adjacent ones of the first color converting portion 241, the second color converting portion 242, and the light-transmitting portion 243.

The partition walls PTT may include an organic material that can absorb or block light.

The color conversion layer 240 may be sealed by the low-refractive layer 260 and the color conversion capping layer 250 bonded together. As a result, the permeation of oxygen or moisture through the color conversion layer 240 can be reduced or delayed.

The color filter layer 220 may selectively transmit light from each of the emission areas EA exiting from the color conversion layer 240 in each of the emission areas EA. In some cases, the upper surface of the color filter layer 220 may be substantially planarized.

The color filter layer 220 may include a first filter portion 221 disposed in the first emission area EA1 and transmits light in the first wavelength range, a second filter portion 222 disposed in the second emission area EA2 and transmits light in the second wavelength range a third filter portion 223 disposed in the third emission area EA3 and transmits light in the third wavelength range, and a light-blocking portion 224 disposed in the non-emission area NEA and the non-display area NDA (see FIG. 1) and blocks light.

Each of the first filter portion 221, the second filter portion 222 and the third filter portion 223 may include a colorant such as a dye and a pigment. A colorant may be a material that absorbs light in a wavelength range other than certain wavelength ranges.

For example, the first filter portion 221 may include a colorant that absorbs light in the other wavelength ranges than the first wavelength range among the lights transmitted through the color conversion layer 240, thereby transmitting light in the first wavelength range.

The second filter portion 222 may include a colorant that absorbs light in wavelength ranges other than the second wavelength range among the light transmitted through the color conversion layer 240, thereby transmitting light in the second wavelength range.

The third filter portion 223 may include a colorant that absorbs light in wavelength ranges other than the third wavelength range among the light transmitted through the color conversion layer 240, thereby transmitting light in the third wavelength range.

The light-blocking portion 224 may include a structure in which two or more of the first filter portion 221, the second filter portion 222 and the third filter portion 223 are stacked on top of one another.

Alternatively, the light-blocking portion 224 may include a material that absorbs light, such as a black matrix material.

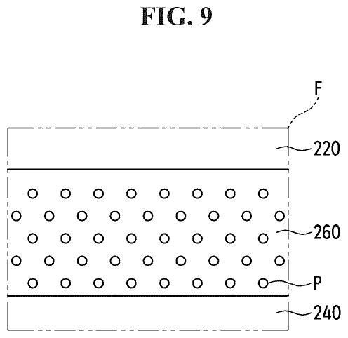

The low-refractive layer 260 may overlap with the emission areas EA of the display area DA. The low-refractive layer 260 may be described in detail with reference to FIG. 9. The low-refractive layer 260 may have a refractive index of approximately 1.0 to 1.4.

Since the emission efficiency of the second substrate 200 can be improved by the low-refractive layer 260, the brightness and display quality of the display device 10 may be improved.

The filling layer 500 may be used to fill the space between the first substrate 100 and the second substrate 200.

The filling layer 500 may be disposed between the encapsulation layer 140 of the first substrate 100 and the color conversion capping layer 250 of the second substrate 200. The filling layer 500 may further function as an adhesive medium that physically bonds the first substrate 100 and second substrate 200.

The filling layer 500 may include an organic material that is transparent and adhesive.

For example, the filling layer 500 may include an organic material such as silicone or epoxy.

The display device according to the embodiment may be applied to a variety of electronic devices. An electronic device according to an embodiment includes the display device described above, and may further include a module or device having additional features in addition to the display device.

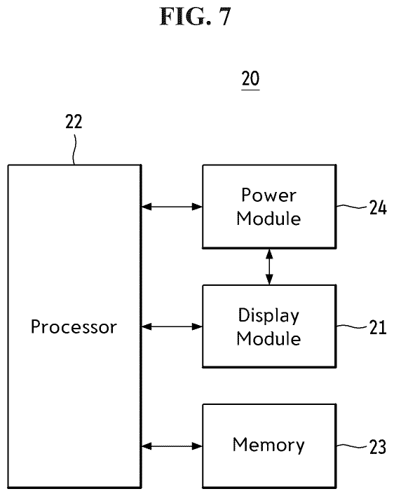

FIG. 7 is a block diagram of an electronic device according to an embodiment of the present disclosure. Referring to FIG. 7, an electronic device 20 may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), or a controller.

The memory 23 may store data for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module that converts the power supplied by the power supply module to generate power required for the operation of the electronic device 20.

At least one of the elements of the electronic device 20 described above may be included in the display device 10 according to the embodiments described above. In addition, some of the individual modules may be included in the display device 10 while some others may be provided separately from the display device 10. For example, the display device 10 may include the display module 21, and the processor 22, the memory 23 and the power module 24 may be provided as other devices inside the electronic device 20 than the display device 10.

In one embodiment, the processor 22, memory 23, and power module 24 may be electrically connected to the display module 21 via internal buses or other interfaces. These interconnections may be implemented using a flexible printed circuit (FPC), board-to-board connectors, or integrated substrates within the electronic device 20.

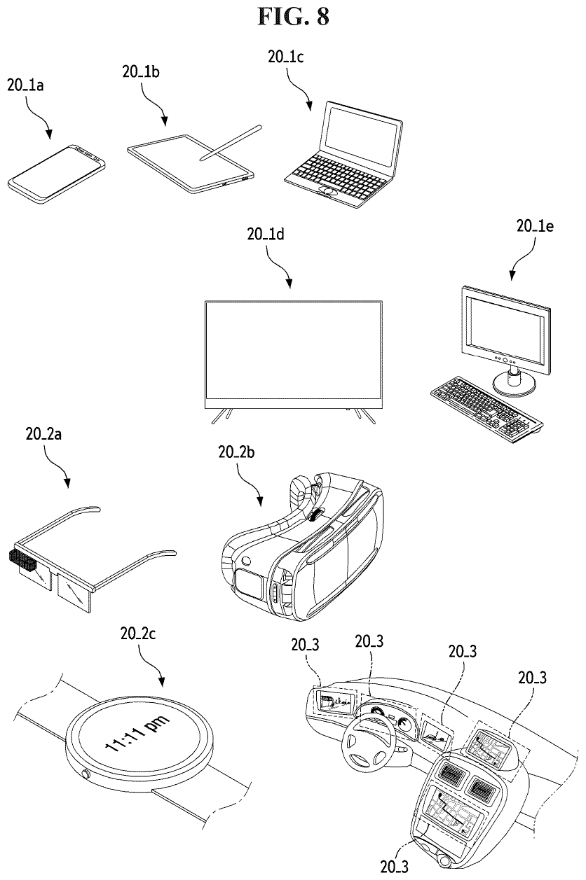

FIG. 8 is a view showing electronic devices according to embodiments of the present disclosure.

Referring to FIG. 8, a variety of electronic devices 20 employing the display devices according to the embodiments may include not only electronic devices for display images such as a smart phone 20_1a, a tablet PC 20_1b, a laptop computer 20_1c, a TV 20_1d and a desktop monitor 20_1e, but also wearable electronic devices including display modules such as smart glasses 20_2a, a head-mounted display 20_2b and a smart watch 20_2c, and electronic devices for vehicles 20_3 including display modules. The electronic devices for vehicles 20_3 may include a center information display (CID) disposed on the dashboard located in the center fascia and the dashboard of a vehicle, and a room mirror display.

Each of the electronic devices 20 shown in FIG. 8 may include at least a display module and processor as illustrated in FIG. 7, and may include additional components such as memory and power modules based on the product configuration. The display device according to the present disclosure may be applicable to a wide range of consumer, wearable, and automotive electronics.

FIG. 9 is a cross-sectional view showing the low-refractive layer in area F of FIG. 6.

Referring to FIG. 9, the low-refractive layer 260 may include pores P.

The cross-sectional shape of the pores P may be substantially spherical and have a diameter of 10 nm to 50 nm.

Since the pores P of the low-refractive layer 260 are formed by mixing hollow silica particles, the size of the pores P may be substantially uniform or the same.

In contrast to conventional methods, the pores were formed by mixing porosen with an organic material and decomposing and vaporizing the porosen with heat. After the porosen has been removed, irregular pores may be formed, rather than pores of a regular shape. For example, irregularly shaped or randomly distributed voids may be formed using the conventional methods. Accordingly, embodiments of the present disclosure enable the formation of uniformly shaped pores by directly incorporating hollow silica.

The low-refractive layer 260 may be silicon oxide (SiOx) having a porosity of 20% to 80%.

As the porosity of the low-refractive layer 260 increases, the refractive index of the low-refractive layer 260 may decrease. For example, the porosity may be referred to as the degree of spaces, holes, or empty regions within a material expressed using a percentage.

The thickness of the low-refractive layer 260 may range from 0.5 μm to 2.0 μm.

The haze of the low-refractive layer 260 may be equal to or less than 0.5%. In some cases, haze refers to the degree to which transmitted light is scattered by a layer, and may be defined as the percentage of light that deviates from the original transmission direction. Lower haze values may indicate higher optical clarity.

To form the low-refractive layer 260 of an organic material on the color conversion layer 240, an organic solution containing 70% to 80% of a solvent may be applied on the color conversion layer 240. In some cases, the solvent contained in the organic solution may damage the color conversion layer 240. To prevent the damage, a capping layer is disposed between the color conversion layer 240 and the low-refractive layer 260.

According to the embodiment of the present disclosure, the damage to the color conversion layer 240 in the display device 10 can be reduced by using a relatively small amount of solvent used for the low-refractive layer 260 even though the low-refractive layer 260 is in contact with the color conversion layer 240.

Light emitted from the light-emitting element LE passes through the first color converting portion 241, the second color converting portion 242, and the light-transmitting portion 243 of the color conversion layer 240. When the refractive index of the color conversion layer 240 is approximately 1.9, the refractive index of the low-refractive layer 260 disposed on the color conversion layer 240 is approximately 1.0 to 1.4. For example, a refractive index mismatch is formed at the interface between the low-refractive layer 260 and the color conversion layer 240. As the refractive index of the low-refractive layer 260 decreases, the critical angle of light transmitted through the color conversion layer 240 may also decrease. As the refractive index of the low-refractive layer 260 decreases, the total reflection may increase. Light emitted from the light-emitting element LE is not directly emitted through the color conversion layer 240 but is totally reflected by the low-refractive layer 260, resulting in a recycling effect. As a result, light emission efficiency of the display device can be increased.

According to the embodiment of the present disclosure, the low-refractive layer 260 may have a haze of 0.5% or less. Since the low-refractive layer 260 has a characteristic of high transparency, scattering properties can be reduced. As a result, image clarity and color fidelity can be maintained.

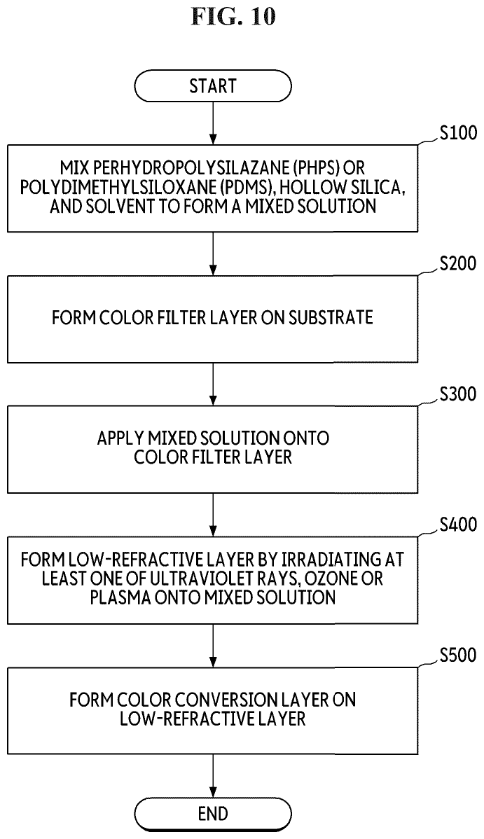

FIG. 10 is a flowchart for illustrating a method for fabricating a display device according to an embodiment of the present disclosure.

Referring to FIG. 10, at step S110, a mixed solution is prepared by mixing perhydropolysilazane (PHPS) or polydimethylsiloxane (PDMS), hollow silica, and a solvent. For example, at step S100, the method includes mixing perhydropolysilazane (PHPS), hollow silica, and a solvent to form a mixed solution. Alternatively, the method includes mixing polydimethylsiloxane (PDMS), hollow silica, and a solvent to form the mixed solution.

Per 100 parts by weight of the mixed solution, the mixed solution may contain 45 to 70 parts by weight of perhydropolysilazane (PHPS) or polydimethylsiloxane, 10 to 40 parts by weight of the hollow silica, and 10 to 20 parts by weight of the solvent.

In an embodiment, per 100 parts by weight of perhydropolysilazane (PHPS) or polydimethylsiloxane, 25 to 30 parts by weight of the solvent and 30 to 80 parts by weight of hollow silica may be used.

The diameter of the cavity of the hollow silica may range from 10 nm to 50 nm.

The content of the hollow silica may be adjusted based on the target porosity of the low-refractive layer 260 to be fabricated.

When the low-refractive layer 260 is fabricated with an organic resin, the refractive index of the organic resin is equal to or greater than 1.6. Since the refractive index of the organic resin is high, a large amount of hollow silica may be needed to sufficiently lower the refractive index.

In contrast, the refractive index of perhydropolysilazane (PHPS) or polydimethylsiloxane used to form the low-refractive layer 260 is lower, at approximately 1.4. Accordingly, a smaller amount of hollow silica is required to achieve a similar refractive index reduction when using perhydropolysilazane (PHPS) or polydimethylsiloxane.

For example, in order to form the low-refractive layer 260 having a refractive index of approximately 1.24 using an organic resin, approximately 60% of the hollow silica of the low-refractive layer 260 is required. In contrast, the low-refractive layer 260 of the present disclosure requires approximately 50% of the hollow silica of the low-refractive layer 260 to achieve a refractive index of approximately 1.24. For example, in order to form the low-refractive layer 260 with the same refractive index, a less amount of the hollow silica is required by using the inorganic material instead of an organic resin.

There is a limit to lowering the refractive index using an organic resin. In contrast, when 80% of hollow silica is used relative to weight of the low-refractive layer 260 fabricated using perhydropolysilazane (PHPS) or polydimethylsiloxane (PDMS), the refractive index of the low-refractive layer 260 may reach approximately 1.09.

When 60 parts by weight of hollow silica is used per 100 parts by weight of the mixed solution, the refractive index of the produced low-refractive layer 260 may be 1.19.

Prior to the preparing the mixed solution (e.g., prior to step 100), the method may further include a step of forming hydroxyl groups on a surface of the hollow silica.

Forming the hydroxyl groups on the surface of the hollow silica may include mixing the hollow silica with sodium hydroxide (NaOH). The hollow silica may be immersed in sodium hydroxide (NaOH) at a concentration of 10 wt % to 30 wt % for a period of time, and then the hollow silica may be washed with a solvent to obtain hollow silica having the hydroxyl groups formed on the surface.

Alternatively, the hollow silica may react with oxygen in the air (or atmospheric oxygen) to form hydroxyl groups on the surface of the hollow silica.

By forming the hydroxyl groups on the surface of the hollow silica, the bonding strength between the hollow silica and perhydropolysilazane (PHPS) or polydimethylsiloxane (PDMS) can be enhanced. The hydroxyl groups formed on the surface of the hollow silica may be bonded with the silicon of perhydropolysilazane or polydimethylsiloxane.

According to an embodiment of the present disclosure, it is possible to reduce the content of the used solvent by using an inorganic material such as perhydropolysilazane (PHPS) and polydimethylsiloxane (PDMS) for the low-refractive layer 260.

The solvent may include at least one of xylene, toluene, anisole, butyl ether, or dibutyl ether. The solvent is not necessarily limited as long as the solvent can dissolve perhydropolysilazane (PHPS) or polydimethylsiloxane (PDMS).

At step 200, a color filter layer 220 is formed on the substrate 210. The color filter layer 220 may be formed using the above-listed materials. The method for forming the color filter layer 220 is not particularly limited herein.

At step 300, the mixed solution is applied onto the color filter layer 220.

The mixed solution may be coated by a slit die coating, dip coating, gravure coating, spin coating, roll coating, bar coating, spray coating, flow coating, or screen coating.

The method may further include removing the solvent after applying the mixed solution.

Removing the solvent may include heat treatment and/or vacuum treatment.

Removing the solvent may include first placing the substrate 210 on which the mixed solution is applied under vacuum. Subsequently, heat may be applied to the substrate 210 to remove the solvent. The substrate 210 may be subject to heat treatment at a temperature of 70° C. to 150° C. for 20 minutes to 100 minutes.

At step 400, at least one of ultraviolet rays, ozone or plasma may be irradiated onto the mixed solution to form a low-refractive layer 260.

The wavelength of ultraviolet rays may be equal to or less than 190 nm.

The atmospheric pressure plasma may be used as the plasma.

By treating with high energy such as ultraviolet rays, ozone and plasma, perhydropolysilazane (PHPS) or polydimethylsiloxane (PDMS) may be converted into silicon oxide (SiOx). Since the mixed solution contains hollow silica with perhydropolysilazane or polydimethylsiloxane, the layer may be converted into silicon oxide (SiOx) including hollow silica by irradiating at least one of ultraviolet light, ozone or plasma.

At step 500, a color conversion layer 240 is formed on the low-refractive layer 260.

The color conversion layer 240 may be formed using the above-listed materials. The method for forming the color conversion layer 240 is not particularly limited herein.

Subsequently, the first substrate 100 including the circuit layer 120, the element layer 130 and the encapsulation layer 140, and the second substrate 200 including the color filter layer 220, the low-refractive layer 260 and the color conversion layer 240 may be bonded together such that the first substrate 100 and the second substrate 200 face each other. A sealing layer 300 may be disposed between the first substrate 100 and the second substrate 200 to attach the first substrate 100 and the second substrate 200.

Although a method for forming the low-refractive layer 260 on the second substrate 200 is described herein as an example, the present disclosure is not necessarily limited thereto. For example, a light-emitting element LE may be formed on the first substrate 100, a color conversion layer 240 may be formed on the light-emitting element LE, and a low-refractive layer 260 may be formed on the color conversion layer 240. In an embodiment, the color filter layer 220 and the low-refractive layer 260 may be formed on different regions of the same substrate and selectively patterned prior to color conversion layer formation.

Although the embodiments of the present invention have been described with reference to the attached drawings, those skilled in the art will understand that the present invention can be implemented in other specific forms without changing the technical idea or essential features of the present invention. Therefore, it should be understood that the embodiments described above are exemplary in all respects and not restrictive.

What is claimed is:

1. A display device comprising:
a substrate;
a light-emitting element disposed on the substrate, wherein the light-emitting element is configured to emit a first light having a first wavelength range;
a color conversion layer disposed on the light-emitting element and configured to convert the first light into a second light having a second wavelength range different from the first wavelength range;
a low-refractive layer disposed on the color conversion layer; and
a color filter layer disposed on the low-refractive layer,
wherein the low-refractive layer comprises silicon oxide (SiOₓ) having a porosity of 20% to 80%, and has a haze of 0.5% or less.

2. The display device of claim 1, wherein:
the low-refractive layer has a refractive index ranges from 1.0 to 1.4.

3. The display device of claim 1, wherein:
the low-refractive layer comprises a plurality of pores, wherein each pore of the plurality of pores has a diameter ranging from 10 nm to 50 nm.

4. The display device of claim 3, wherein:
the plurality of pores of the low-refractive layer are substantially spherical.

5. The display device of claim 1, wherein:
the low-refractive layer has a thickness of 0.5μm to 2.0μm.

6. A method for fabricating a display device, the method comprising:
mixing perhydropolysilazane (PHPS) or polydimethylsiloxane (PDMS), hollow silica, and a solvent to form a mixed solution;
forming a color filter layer on a substrate;
applying the mixed solution onto the color filter layer;
forming a low-refractive layer by irradiating at least one of ultraviolet rays, ozone, or plasma onto the mixed solution; and
forming a color conversion layer on the low-refractive layer.

7. The method of claim 6, wherein:

100. parts by weight of the mixed solution comprises 45 to 70 parts by weight of the PHPS or the PDMS, 10 to 40 parts by weight of the hollow silica, and 10 to 20 parts by weight of the solvent.

8. The method of claim 6, wherein:
the hollow silica includes a cavity having a diameter ranging from 10 nm to 50 nm.

9. The method of claim 6, wherein:
the solvent comprises at least one of xylene, toluene, anisole, butyl ether, or dibutyl ether.

10. The method of claim 6, wherein:
the ultraviolet rays have a wavelength of 190 nm or less.

11. The method of claim 6, further comprising:
removing the solvent from mixed solution on the color filter layer.

12. The method of claim 11, wherein removing the solvent comprises:
performing at least one of heat treatment or vacuum treatment.

13. The method of claim 6, further comprising:
forming hydroxyl groups on a surface of the hollow silica.

14. The method of claim 13, wherein forming the hydroxyl groups on the surface of the hollow silica comprises:
mixing the hollow silica with sodium hydroxide (NaOH).

15. The method of claim 13, wherein forming the hydroxyl groups on the surface of the hollow silica comprises:
exposing the hollow silica to atmospheric oxygen.

16. The method of claim 6, wherein:
the low-refractive layer has a haze equal to or less than 0.5%.

17. The method of claim 6, wherein:
the low-refractive layer has a refractive index ranging from 1.0 m to 1.4.

18. The method of claim 6, wherein:
the hollow silica has a substantially spherical cross-sectional shape.

19. The method of claim 6, wherein:
the low-refractive layer has a thickness ranging from 0.5 μm to 2.0 μm.

20. An electronic device comprising:
a display device for displaying images,
wherein the display device comprises:
a substrate;
a light-emitting element disposed on the substrate, where the light-emitting element is configured to emit a first light having a first wavelength range;
a color conversion layer disposed on the light-emitting element and configured to convert the first light into a second light having a second wavelength range different from the first wavelength range;
a low-refractive layer disposed on the color conversion layer; and
a color filter layer disposed on the low-refractive layer, and
wherein the low-refractive layer comprises silicon oxide (SiOₓ) having a porosity of 20% to 80%, and has a haze of 0.5% or less.
